(19) United States
(12) Patent Application Publication
(10) Pub. No.: US 2008/0203641 A1
(43) Pub. Date: Aug. 28, 2008

(54) End Effector For Handling Sputter Targets

(75) Inventors: Wiley Zane Reed, Greenville, SC (US); Bobby R. Cosper, Trenton, GA (US); Kenneth G. Schmidt, Piedmont, SC (US); Neil D. Bultz, Greenville, SC (US); David M. Nozicka, Wellsburg, IA (US)

Correspondence Address: WEGMAN, HESSLER & VANDERBURG, 6055 ROCKSIDE WOODS BOULEVARD, SUITE 200, CLEVELAND, OH, 44131, US

(73) Assignee: Tosoh SMD ETNA, LLC, Grove City, OH (US)

(21) Appl. No.: 11/795,560

(22) PCT Filed: Jan. 18, 2006
(86) PCT No.: PCT/US06/01723

§ 371 Date: Aug. 21, 2007

Related U.S. Application Data
(60) Provisional application No. 60/644,929, filed on Jan. 19, 2005.

(51) Int. Cl. B25B 5/00; C23C 14/00

(52) U.S. Cl. 269/282; 204/298.12

(57) ABSTRACT

A fixture and method is provided for gripping an article, such as a sputtering target. The fixture comprises a base, a first set of contact rollers, and a second set of contact rollers, wherein at least one of the first set and the second set are adjustably positioned relative to the other of the first set and the second set on the base. The contact rollers can be configured as v-grooved wheels that will only touch chamfered portions of an outer diameter of the sputtering target when the contact rollers are clamped against the sputtering target. At least one of the first set and the second set of contact rollers can be pivotally mounted on a slide, with the slide being adjustably positioned on the base of the fixture.

This application claims the benefit of U.S. Provisional Patent Application No. 60/644,929 filed Jan. 19, 2005, which is incorporated in its entirety by reference herein. The present invention relates to devices and methods used in the handling of articles, such as metal articles, like sputtering targets.

### SUMMARY

According to various embodiments, a fixture is provided for gripping and handling an article, such as a sputtering target during the manufacturing of the sputtering target, wherein the fixture comprises a base, and first and second sets of contact rollers, for example, grooved wheels, wherein at least one of the first set and the second set of contact rollers are adjustably positioned relative to the other of the first set and the second set of contact rollers on the base.

According to various embodiments, a sputtering target holding fixture is provided comprising a base, a first pair of contact rollers, each of the first pair of contact rollers being rotatably mounted on a support member, each of the support members for the first pair of contact rollers being supported in and resiliently biased relative to a fixed stanchion fixedly mounted on the base, and a second pair of contact rollers, each of the second pair of contact rollers being rotatably mounted on a support member, each of the support members for the second pair of contact rollers being supported in and resiliently biased relative to a pivotal and axially movable stanchion pivotally and axially movably mounted on the base. Besides sputtering targets, other articles can benefit from this fixture.

According to various embodiments, a method of automatically processing a sputtering target is provided. The method includes providing a holding fixture comprising first and second pairs of contact rollers, each of the first pair of contact rollers being rotatably mounted on a support member, each of the support members for the first pair of contact rollers being supported in and resiliently biased relative to a fixed stanchion fixedly mounted on a base, and each of the second pair of contact rollers being rotatably mounted on a support member, each of the support members for the second pair of contact rollers being supported in and resiliently biased relative to a pivotal and axially movable stanchion pivotally and axially movably mounted on the base. The method further includes moving the pivotally and axially movable stanchion along the base of the holding fixture away from the fixed stanchion, positioning the holding fixture over a sputtering target wherein the second pair of contact rollers are aligned with a contact portion of the sputtering target, moving the holding fixture to bring the first pair of contact rollers into contact with the contact portion of the sputtering target, and moving the pivotally and axially movable stanchion toward the fixed stanchion to clamp the sputtering target between the first and second pairs of contact rollers.

Additional features and advantages of the present teachings will be set forth in part in the description that follows, and in part will be apparent from the description, or may be learned by practice of the present teachings. The objectives and other advantages of the present teachings will be realized and attained by means of the elements and combinations particularly pointed out in the description that follows.

It is to be understood that both the foregoing general description and the following detailed description are exemplary and explanatory only and are intended to provide a further explanation of the present teachings.

### BRIEF DESCRIPTION OF THE DRAWINGS

Various embodiments of the present teachings are exemplified in the accompanying drawings. The teachings are not limited to the embodiments depicted in the drawings, and include equivalent structures and methods as set forth in the following description and as would be known to those of ordinary skill in the art in view of the present teachings. In the drawings:

FIG. 1 shows a perspective view of a fixture for gripping a sputtering target according to various embodiments;

FIG. 2 shows a side elevation view of the fixture shown in FIG. 1; and

FIG. 3 shows a top plan view of the fixture shown in FIGS. 1 and 2, according to various embodiments.

### DESCRIPTION OF VARIOUS EMBODIMENTS

The present teachings relate to a fixture for gripping an article, for instance, sputtering target during processing of the sputtering target. Sputtering targets are used for many purposes, including producing thin films of metals or compounds. In a sputtering process, a source material is bombarded with plasma ions that dislodge or eject atoms from the surface of a sputter target. The ejected atoms are deposited atop a substrate to form a film coating that is typically several atomic layers thick.

Sputtering targets can be made from a variety of metals, such as valve metal materials. Valve metals generally include tantalum, niobium, and alloys thereof, and also may include metals of Groups IVB, VB, VIB, and alloys thereof. Valve metals are described, for example, by Diggle in “Oxides and Oxide Films”, Vol. 1, pages 94-95, 1972, Marcel Dekker, Inc., New York, incorporated in its entirety by reference herein.

Films having uniform chemistry and thickness are desired for diffusion barrier applications. To obtain uniform chemistry and thickness, it is desirable to sputter a target having certain desirable properties, including, high purity, a fine grain size, homogeneous texture void of strong texture bands, and accurately machined sputtering surfaces. The expense of the material used in a sputtering target and the criticality of dimensions on the machined surfaces of the sputtering target make it desirable to provide a handling fixture that is adapted to grip the sputtering target without touching critical machined surfaces. The fixture for gripping a sputtering target is also desirably able to hold parts with varying diameters and thicknesses.

According to various embodiments of the present teachings, a fixture is provided wherein the fixture can be attached, for example, to a manipulation or robot (e.g., a multi-axis robot, like a six-axis robot), which enables movement and manipulation of the fixture to pick or place sputtering targets in any orientation during various processes.

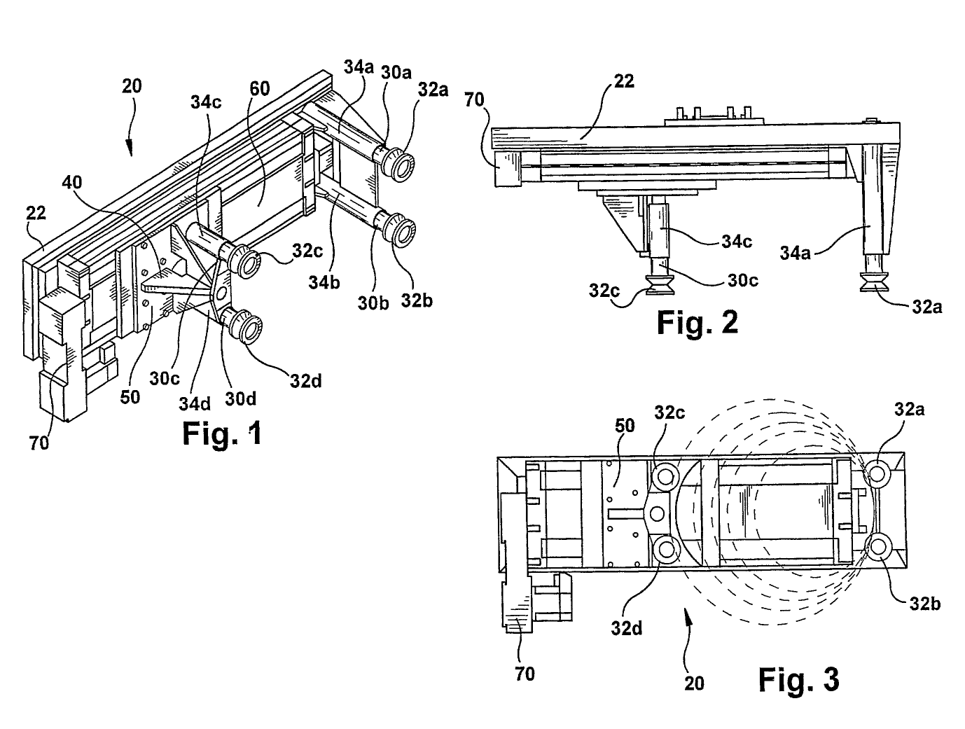

Referring initially to FIG. 1, a fixture 20 for gripping a sputtering target can comprise a base 22 wherein the base comprises a slide 40 that is axially movable along the base 22 on a grooved top surface 60 of the base 22. Fixed stanchions 34a, 34b can be provided at one end of the base 22, wherein the fixed stanchions 34a, 34b provide support for support members 30a, 30b, which can be resiliently biased relative to, and slidably mounted in the fixed stanchions 34a, 34b. Each of the resiliently biased support members 30a, 30b can rotatably support a respective contact roller 32a, 32b. The contact rollers can be any design. The contact rollers 32a, 32b can comprise v-grooved wheels or other rotatable members having outer peripheral surfaces configured for contact with portions of a sputtering target that will not affect a finished machined surface of the sputtering target.

The axially movable slide 40 can be mounted for axial movement along the top surface 60 of the base 22, and a ball screw type actuator 70 can be provided, mounted to the base 22 and connected to the slide 40 for moving the slide 40 along the top surface 60 of the base 22 toward and away from the fixed stanchions 34a, 34b. Although the present teachings refer to a ball screw type actuator 70, one of ordinary skill will recognize that other means for moving the slide 40 along the base 22 can be provided, including, but not limited to a linear actuator, a hydraulic actuator, and a rack and pinion gear type actuator.

Pivotal stanchions 34c, 34d can be provided on the slide 40, and can be pivotally mounted through a pivotal fixture 50 to the slide 40. Resiliently biased support members 30c, 30d can be slidably supported within the pivotal stanchions 34c, 34d, with each of the resiliently biased support members 30c, 30d rotatably mounting contact rollers 32c, 32d. The contact rollers 32c, 32d, similar to contact rollers 32a, 32b, can be provided as v-grooved wheels, or other rotatable members with specially designed contact surfaces, wherein the contact rollers 32a, 32b, 32c, 32d can be configured to clamp against a sputtering target diameter, and wherein each of the contact rollers will touch, for example, only the small chamfers on the outer periphery of a flange extending from the sputtering target outer diameter.

The actuator 70 connected to the slide 40 can also comprise a servo drive, wherein the servo drive is adapted to receive feedback signals indicative of at least one of a clamping torque exerted by the second pair of contact rollers 32c, 32d against a sputtering target and a position of the second pair of contact rollers 32c, 32d. The pivotal assembly 50 on which the stanchions 34c, 34d are mounted, along with the resiliently biased feature of the support members 30c, 30d and the rotatably mounted feature of the contact rollers 32c, 32d allow the contact rollers to be clamped against a sputtering target with the desired amount of torque and at the desired position, while allowing the contact rollers to rotate so that they will not mar the machined surfaces when the contact rollers clamp against the sputtering target.

A method of clamping a sputtering target according to various embodiments can comprise moving the pivotal assembly 50 along with pivotal and axially movable stanchions 34c, 34d on slide 40 along the base 22 toward and away from the fixed stanchions 34a, 34b. The distance which the slide 40, pivotal assembly 50, and pivotal stanchions 34c, 34d are moved away from the fixed stanchions 34a, 34b can be a function of the size of the sputtering target which is to be gripped by the fixture 20.

After moving the pivotal and axially movable stanchions 34c, 34d along the top surface 60 of base 22 away from the fixed stanchions 34a, 34b by a distance large enough to clear the outer diameter of a sputtering target, the holding fixture 20 can then be positioned over the sputtering target wherein the second pair of contact rollers 32c, 32d are aligned with, but spaced from a contact portion of the sputtering target. The pivot assembly 50 on slide 40 allows the pivotal stanchions 34c, 34d to move relative to the slide 40, in addition to the movement of slide 40 along top surface 60 of base 22. Furthermore, the resiliently biased support members 30c, 30d rotatably support contact rollers 32c, 32d and allow these rollers to move in a direction parallel to the axes of the pivotal stanchions 34c, 34d.

The holding fixture 20 can be moved into position relative to the sputtering target such that the pair of contact rollers 32c, 32d are aligned with a contact portion of the sputtering target. The holding fixture 20 can then be moved to bring the first pair of contact rollers 32a, 32b on support members 30a, 30b, and fixed stanchions 34a, 34b, into contact with the contact portion of the sputtering target on the side of the sputtering target opposite from the contact portion of the sputtering target aligned with contact rollers 32c, 32d. The method of clamping the sputtering target using the fixture 20 can then comprise moving the pivotal and axially movable stanchions 34c, 34d toward the fixed stanchions 34a, 34b to clamp the sputtering target between the first pair of contact rollers 32a, 32b and the second pair of contact rollers 32c, 32d. The resiliently biased support members 30c, 30d and the rotatably mounted contact rollers 32c, 32d, as well as rotatably mounted and resiliently biased contact rollers 32a, 32b allow for slight inaccuracies in the alignment of the contact rollers with the contact portions of the sputtering target. Furthermore, the servo drive feature of the actuator 70 allows for adjustment of the position of the contact rollers and adjustment of the clamping torque applied by the contact rollers against the sputtering target based on feedback signals provided to the servo drive of actuator 70.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

What is claimed is:

1. A fixture for gripping an article, comprising:
a base; and
a first set of contact rollers and a second set of contact rollers, at least one of the first set and the second set being adjustably positioned relative to the other of the first set and the second set on the base.

2. The fixture of claim 1, wherein at least one of the first set and the second set of contact rollers is pivotally mounted on a slide, and the slide is adjustably positioned on the base.

3. The fixture of claim 1, wherein at least one of the first set and the second set of contact rollers comprises grooved wheels rotatably mounted and resiliently biased relative to the base.

4. A sputtering target holding fixture, comprising:
a base;
a first pair of contact rollers, each of the first pair of contact rollers being rotatably mounted on a support member, each of the support members for the first pair of contact rollers being slidably supported in and resiliently biased relative to a fixed stanchion fixedly mounted on the base; and
a second pair of contact rollers, each of the second pair of contact rollers being rotatably mounted on a support member, each of the support members for the second pair of contact rollers being slidably supported in and resiliently biased relative to a pivotal and axially movable stanchion pivotally and axially movably mounted on the base.

5. The sputtering target holding fixture of claim 4, wherein each of the contact rollers comprises a v-grooved wheel.

6. The sputtering target holding fixture of claim 4, further including a slide adapted to be axially movable along the base, toward and away from the fixed stanchion, the pivotal and axially movable stanchion being pivotally mounted on the slide.

7. The sputtering target holding fixture of claim 6, further including an actuator connected to the slide and adapted to controllably move the slide relative to the base.

8. The sputtering target holding fixture of claim 7, wherein the actuator comprises a ball screw actuator and a servo drive attached to the ball screw actuator.

9. The sputtering target holding fixture of claim 8, wherein the servo drive is adapted to receive feedback signals indicative of at least one of a clamping torque exerted by the second pair of contact rollers against a sputtering target and a position of the second pair of contact rollers.

10. A method of automatically processing a sputtering target, comprising:
providing a holding fixture comprising first and second pairs of contact rollers, each of the first pair of contact rollers being rotatably mounted on a support member, each of the support members for the first pair of contact rollers being slidably supported in and resiliently biased relative to a fixed stanchion fixedly mounted on a base, and each of the second pair of contact rollers being rotatably mounted on a support member, each of the support members for the second pair of contact rollers being slidably supported in and resiliently biased relative to a pivotal and axially movable stanchion pivotally and axially movably mounted on the base;
moving the pivotal and axially movable stanchions along the base away from the fixed stanchions;
positioning the holding fixture over a sputtering target wherein the second pair of contact rollers are aligned with a contact portion of the sputtering target;
moving the holding fixture to bring the first pair of contact rollers into contact with the contact portion of the sputtering target; and
moving the pivotal and axially movable stanchions toward the fixed stanchions to clamp the sputtering target between the first and second pairs of contact rollers.

11. The method of claim 10, wherein a ball screw actuator is provided to move the pivotal and axially movable stanchions toward the fixed stanchions.

12. The method of claim 10, wherein a linear actuator is provided to move the pivotal and axially movable stanchions toward the fixed stanchions.

13. The method of claim 10, wherein an actuator is connected to the pivotal and axially movable stanchions and a servo drive is attached to the actuator, the servo drive receiving a feedback signal indicative of at least one of a clamping torque exerted by the second pair of contact rollers against the sputtering target and a position of the second pair of contact rollers.

14. The method of claim 13, wherein the servo drive controls the amount of clamping torque applied to the sputtering target as a function of the feedback signal.

15. The method of claim 13, wherein the servo drive controls the position of the second pair of contact rollers as a function of the feedback signal.

16. A fixture for gripping a sputtering target during processing of the sputtering target, comprising:
a base;
a slide movably mounted on the base;
a first assembly of fixed stanchions fixedly mounted on the base, a pair of support members slidably mounted in and resiliently biased relative to the first assembly of fixed stanchions, and a pair of contact rollers rotatably mounted on the pair of resiliently biased support members; and
a second assembly of pivotal stanchions pivotally mounted on the slide, the pair of pivotal stanchions supporting a second pair of support members slidably mounted in and resiliently biased relative to the second assembly of pivotal stanchions, and a second pair of contact rollers rotatably mounted on the resiliently biased second pair of support members.

17. The fixture of claim 16, further including an actuator mounted on the base and connected to the slide.

18. The fixture of claim 17, further including a servo drive connected to the actuator.

19. The fixture of claim 16, further including a ball screw type actuator mounted on the base and connected to the slide.

20. The fixture of claim 19, further including a servo drive connected to the actuator and adapted to receive feedback signals indicative of at least one of the position of the slide and a torque exerted by the second pair of contact rollers against a sputtering target.
